(19) United States
(12) Patent Application Publication
(10) Pub. No.: US 2013/0156937 A1
(43) Pub. Date: Jun. 20, 2013

(54) System and Method for Aligning Sputter Sources

(71) Applicants: Danny Wang, Saratoga, CA (US); Kent Riley Child, Dublin, CA (US); Owen Ho Yin Fong, San Jose, CA (US)

(72) Inventors: Danny Wang, Saratoga, CA (US); Kent Riley Child, Dublin, CA (US); Owen Ho Yin Fong, San Jose, CA (US)

(73) Assignee: Intermolecular, Inc., San Jose, CA (US)

(21) Appl. No.: 13/328,530

(22) Filed: Dec. 16, 2011

(51) Int. Cl. C23C 16/52; B05C 11/00

(52) U.S. Cl. 427/8; 118/712

(57) ABSTRACT

Embodiments provided herein describe systems and methods for aligning sputtering sources, such as in a substrate processing tool. The substrate processing tool includes at least one sputtering source and a device. Each of sputtering sources includes a target having a central axis. The device has an axis and is detachably coupled to the at least one sputtering source. The device indicates to a user a direction in which the central axis of the target of the at least one sputtering source is oriented.

The present invention relates to substrate processing. More particularly, this invention relates to systems and methods for aligning sputtering sources used to deposit materials on substrates.

### BACKGROUND OF THE INVENTION

Physical vapor deposition (PVD) processes, such as sputtering, involve depositing materials onto a substrate by ejecting material from a target (or sputtering) source that includes the materials to be deposited. When PVD processes are used to form thin films, such as in semiconductor processing, the quality and uniformity of the thin films may be compromised if the target sources are not properly aligned (or oriented) relative to the substrate. The optimal alignment of the target sources may depend on the particular PVD processes being used, as well as the materials being deposited.

Conventional methods for target source alignment involve the use of digital levelers to estimate and appropriately adjust the alignment of the target sources. Such methods are time consuming and sometimes result in improper alignment.

### BRIEF DESCRIPTION OF THE DRAWINGS

Various embodiments of the invention are disclosed in the following detailed description and the accompanying drawings:

FIG. 1 is an isometric view of a sputtering source and an alignment device according to one embodiment of the present invention;

FIG. 2 is an isometric view of the sputtering source and the alignment device of FIG. 1, illustrating the alignment device being attached to the sputtering source;

FIG. 3 is a cross-sectional view of the sputtering source and the alignment device taken along line 3-3 in FIG. 2;

FIGS. 4-6 are simplified cross-sectional views of a physical vapor deposition (PVD) tool, illustrating a method for aligning sputtering sources according to one embodiment of the present invention;

FIG. 7 is a schematic diagram of a combinatorial processing and evaluation technique; and

FIG. 8 is a simplified schematic diagram illustrating a general methodology for combinatorial process sequence integration.

### DETAILED DESCRIPTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

Embodiments described herein provide systems (and/or methods) for indicating the direction a sputtering source (or a target or gun) is pointing or facing. More particularly, the system allows a user to easily determine, and perhaps adjust, the direction in which the central axis of the sputtering source is oriented. This is accomplished by temporarily attaching an alignment, or pointing, device to the sputtering source. The alignment device provides an indication of a direction in which the central axis of the sputtering source (or a target of the sputtering source) is oriented.

In one embodiment, a substrate processing tool (e.g., a physical vapor deposition (PVD) tool) is provided that includes a sputtering source having a target and an alignment device that is detachably coupled to the sputtering source. The alignment device indicates to a user a direction in which the central axis of the target of the sputtering source is oriented.

The alignment device may indicate an alignment axis extending from the target of the sputtering source, which may be parallel, or even congruent with, the central axis of the target. The alignment device may include an electromagnetic radiation source, such as a laser, which is configured to emit electromagnetic radiation along the alignment axis. In other embodiments, the alignment device may simply include an elongate member that extends from the sputtering source in such a way to indicate the direction the sputtering source is facing.

The alignment device allows the user to easily determine how the sputtering source is aligned relative to, for example, a substrate or an aperture above a substrate. In some embodiments, the angular orientation and the position (e.g., height) of the sputtering source are adjustable. As such, the user may use the alignment device to adjust the position and orientation of the sputtering source as desired (e.g., depending on the sputtering process). The pointing device may be used in systems having a single sputtering source, as well as those having multiple sputtering sources, such as “combinatorial” systems.

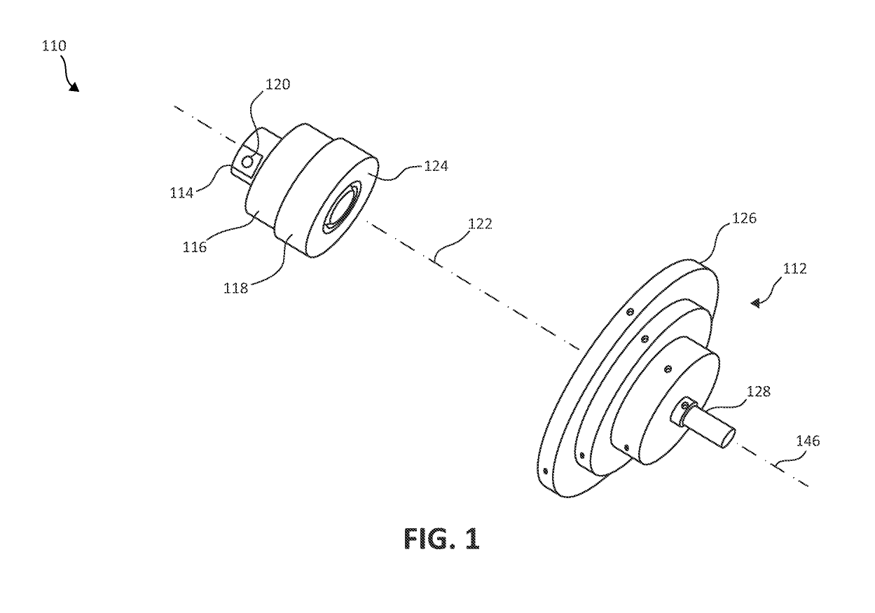

FIGS. 1-3 illustrate a sputtering source 110 for a substrate processing tool and an alignment device 112, according to one embodiment of the present invention. The sputtering source 110 includes a mounting joint 114, a target electrode 116, and a target 118. The mounting joint 114 is connected to a side of the target electrode 116 opposing the target 118 and includes a mounting aperture 120 extending therethrough. As will be described in greater detail below, the mounting joint 114 may be used to secure the sputtering source 110 within a processing chamber of a substrate processing tool such that the angular orientation of the sputtering source 110 may be adjusted.

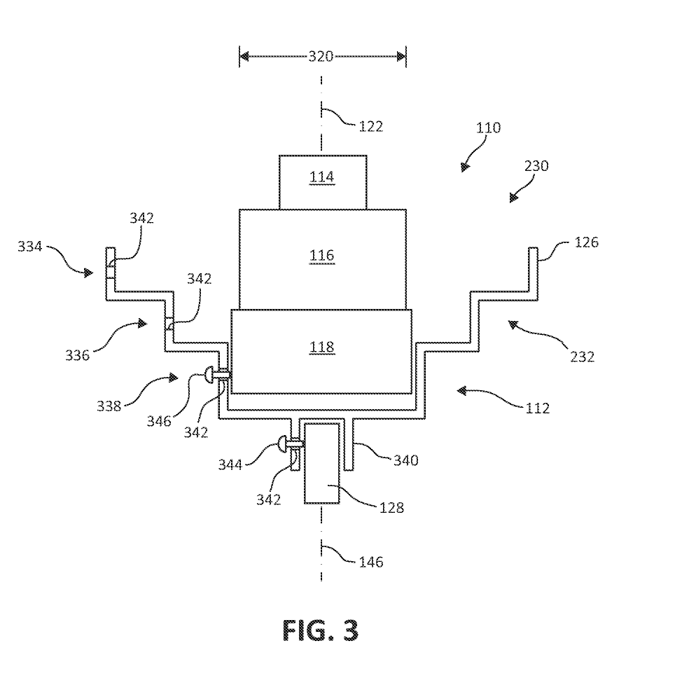

The target 118 is secured to the target electrode 116 and includes a material (e.g., silver, nickel, chromium, etc.) to be sputtered onto a surface of a substrate. In the depicted embodiment, target electrode 116 and the target 118 are substantially circular. However, in other embodiments, different shapes may be used. The sputtering source 110, specifically the target 118, may have a width, or diameter, 320 (FIG. 3) of, for example, approximately 5 centimeters (cm). However, as described below, in other embodiments, the sputtering source 110 may have different sizes. Additionally, the target 118 has a central axis 122 extending through a central portion thereof, which is perpendicular to a surface 124 opposing the target electrode 118.

Still referring to FIGS. 1-3, the alignment device 12 includes a body 126 and an alignment (or pointing) mechanism 128. In the depicted embodiment, the body 126 is substantially circular and has a concave back side 230 and a convex front side 232. Referring specifically to FIG. 3, the body 126 is shaped to have a series of concentric “tiers” 334, 336, and 338, with varying widths or diameters, on the back side 230 and a flange 340 on the front side 232, adjacent to tier 338. As shown in FIG. 3, each of the tiers 334, 336, and 338 and the flange 340 include a fastener opening 342 extending therethrough.

The alignment mechanism 128 is inserted into the flange 340 and secured in place with a fastener 344 (e.g., a screw) extending through the fastener opening 342 of the flange 340. In one embodiment, the alignment mechanism 128 is an electromagnetic radiation source, such as a laser. In such an embodiment, when activated, the electromagnetic radiation source emits electromagnetic radiation along an alignment axis 146, which extends through a central portion of the body 126 of the alignment device 112 and is concentric with the tiers 334, 336, and 338. Although not shown, in other embodiments, the alignment mechanism 128 may include an elongate member (e.g., a “pointer”) extending from the body 126 of the alignment device 112 along the alignment axis 146.

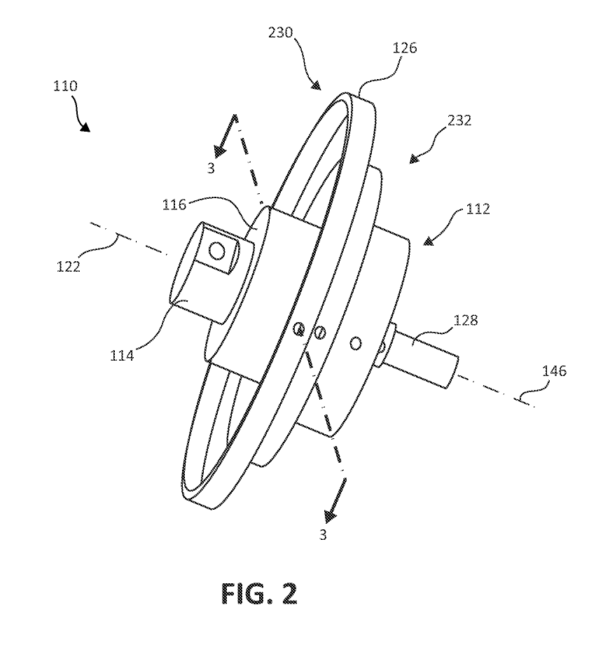

Referring specifically to FIGS. 2 and 3, the alignment device 112 is detachably connected to the sputtering source 110 in such a way that the central axis 122 of the target 118 and the alignment axis 146 of the alignment device 112 are parallel. In the particular embodiment shown, the central axis 122 of the target 118 and the alignment axis 146 of the alignment device 112 are congruent. More particularly, the sputtering source 110 is inserted into the back side 230 of the body 126 of the alignment device 112 such that the target 118 mates with tier 338. That is, tier 338 is sized and shaped to fit the particular target 118 (e.g., 5 cm diameter) shown.

However, it should be understood that the alignment device 112 may also be used with targets of different sizes, as provided by tiers 334 and 336. For example, tier 334 may be sized to fit, for example, a target with a diameter of 20 cm, and tier 336 may be sized to fit, for example, a target with a diameter of 10 cm.

In the depicted embodiment, the body 126 of the alignment device 112 is secured to the sputtering source 110 with a fastener 346 (e.g., a screw) extending through the fastener opening 342 through tier 338 of the body 126, which contacts the target 118. As such, the alignment device 112 may be removed from the sputtering source 110 by loosening the faster 346.

Thus, when the alignment device 112 is attached to the sputtering source 110, the alignment mechanism 128 provides an indication of the angular orientation of the target 118 to a user. More specifically, the alignment mechanism 128 indicates a direction in which the central axis 122 of the target 118 is oriented. As is described below, this indication may be used to adjust the angular orientation (and/or position) of the sputtering source 110 as appropriate given particular processing conditions.

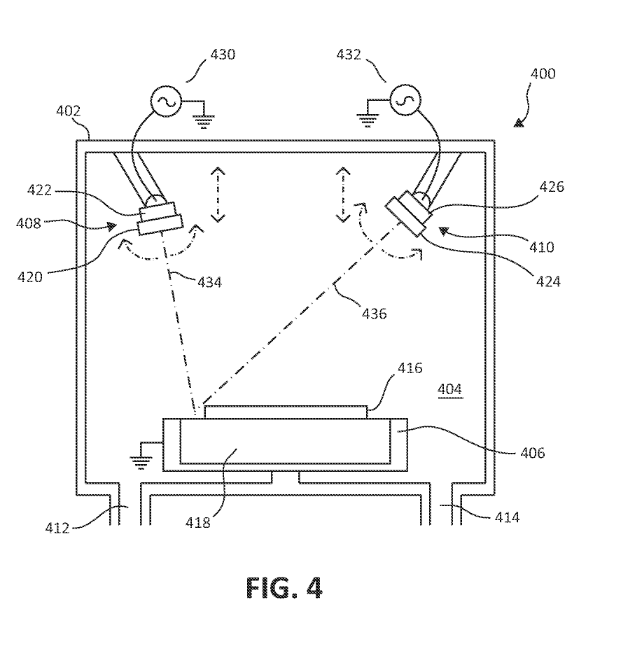

FIGS. 4-6 illustrate a substrate processing tool 400 and a method for aligning sputtering sources within the substrate processing tool 400, according to one embodiment of the present invention. The substrate processing tool 400 may be a PVD tool, as is commonly understood. The substrate processing tool 400 includes a housing 402 that defines, or encloses, a processing chamber 404, a substrate support 406, a first sputtering source 408, and a second sputtering source 410.

The housing 402 includes a gas inlet 412 and a gas outlet 414 near a lower region thereof on opposing sides of the substrate support 406. The substrate support 406 is positioned near the lower region of the housing 402 and in configured to support a substrate 416. The substrate 416 may be, for example, a round semiconductor (e.g., silicon) substrate, or a glass (e.g., borosilicate glass) substrate, having a diameter of, for example, 200 mm or 300 mm. In other embodiments (such as in a manufacturing environment), the substrate 416 may have other shapes, such as square or rectangular, and may be significantly larger (e.g., 0.5-6 m across), particularly when the substrate 416 is glass. The substrate support 406 includes a support electrode 418 and is held at ground potential during processing, as indicated.

The first and second sputtering sources 408 and 410 are suspended from an upper region of the housing 402 within the processing chamber 404. The first and second sputtering sources 408 and 410 may be similar to sputtering source 10 described above. Thus, the first sputtering source 408 includes a first target 420 and a first target electrode 422, and the second sputtering source 410 includes a second target 424 and a second target electrode 426.

The first and second sputtering sources 408 and 410 are coupled to the housing 402 such that the angular orientation thereof may me adjusted by a user (e.g., via mounting joint 14 in FIG. 1). Additionally, the sputtering sources 408 and 410 may be coupled to the housing 402 such that their position within the processing chamber 404 (e.g., the distance between the sputtering sources 408 and 410 and the substrate 416) may be adjusted.

The materials used in the targets 420 and 424 may, for example, include tin, zinc, antimony, silicon, strontium, titanium, niobium, zirconium, magnesium, aluminum, yttrium, lanthanum, hafnium, bismuth, silicon, silver, nickel, chromium, or any combination thereof (i.e., a single target may be made of an alloy of several metals). Additionally, the materials used in the targets may include oxygen, nitrogen, or a combination of oxygen and nitrogen in order to form the oxides, nitrides, and oxynitrides. Additionally, although only two sputtering sources 408 and 410 (and targets 420 and 224) are shown in the depicted embodiment, additional sputtering sources (and targets) may be used.

Still referring to FIG. 4, the substrate processing tool 400 also includes a first power supply 430 coupled to the first target electrode 422 and a second power supply 432 coupled to the second target electrode 424. As is commonly understood, the power supplies 430 and 432 pulse direct current (DC) power to the respective electrodes, causing material to be, at least in some embodiments, simultaneously sputtered (i.e., co-sputtered) from the first and second targets 420 and 424.

During sputtering, inert gases, such as argon or krypton, may be introduced into the processing chamber 404 through the gas inlet 412, while a vacuum is applied to the gas outlet 414. However, in embodiments in which reactive sputtering is used, reactive gases may also be introduced, such as oxygen and/or nitrogen, which interact with particles ejected from the targets (i.e., to form oxides, nitrides, and/or oxynitrides).

Although not shown in FIGS. 4-6, the PVD tool 400 may also include a control system having, for example, a processor and a memory, which is in operable communication with the other components shown in FIG. 4-6 and configured to control the operation thereof in order to perform the methods described herein.

As shown in FIG. 4, the first sputtering source 408 is initially oriented such that a central axis 434 of the first target 420 intersects the substrate support 406 to the left (as viewed in FIG. 4) of the substrate 416. Similarly, the second sputtering source 410 is initially oriented such that a central axis 436 of the second target 424 intersects the substrate support 406 to the left of the substrate 436.

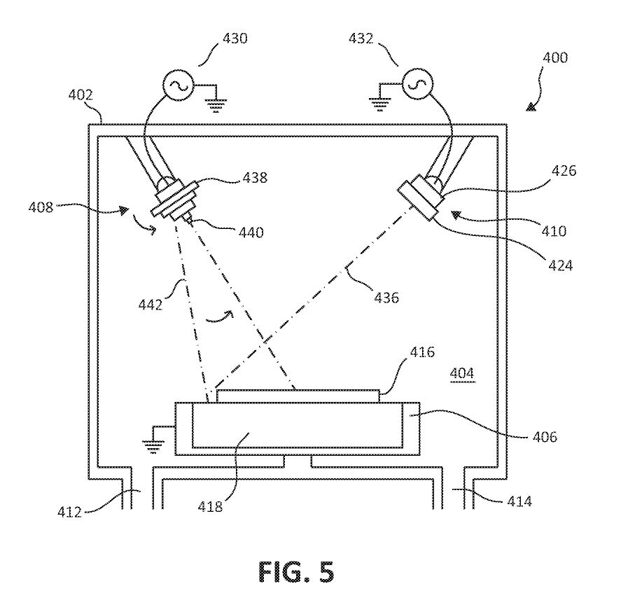

Referring to FIG. 5, an alignment device 438 (e.g., the alignment device 12 described above) is then attached to the first sputtering source 408 in, for example, a manner similar to that described above such that the alignment mechanism 440 (e.g., a laser) emits electromagnetic radiation along the alignment axis 442, which is congruent with the central axis 434 (FIG. 4) of the first target 420.

Thus, a user may easily determine the orientation of the first sputtering source 408 by locating the illumination caused by the laser. In the example shown, when the alignment device 438 is initially attached to the first sputtering source 408, the illumination caused by the laser is a spot on the substrate support 416 to the left of the substrate 416. However, as shown, the user may then (e.g., manually) rotate the first sputtering source 408 so that the illumination is moved, for example, onto a central portion of the substrate 416, thus directing the central axis 434 of the first target 420 towards the central portion of the substrate 416.

In this manner, the user is able to easily determine, and adjust, the orientation of the first target 420. As a result, the overall quality and uniformity of the layers formed on the substrate 416 may be improved.

Although not specifically shown, the alignment device 438 may then be removed from the first sputtering source 408 and attached to the second sputtering source 410. The second sputtering source 410 may then be similarly aligned.

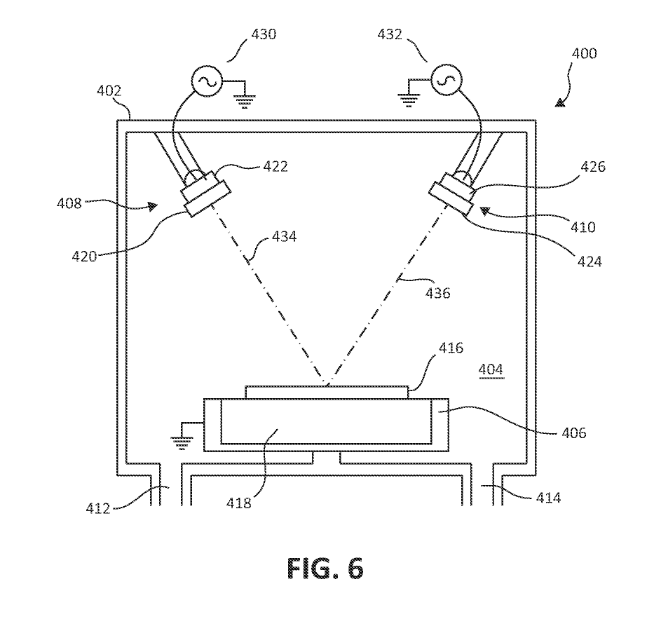

FIG. 6 illustrates the substrate processing tool 400 after the first sputtering source 408 and the second sputtering source 410 have been aligned. As shown, the central axis 434 of the first target 420 and the central axis 436 of the second target 424 are both directed towards the central portion of the substrate 416.

Although in the embodiment shown in FIGS. 4-6 the sputtering sources 408 and 410 (and the targets 420 and 424) are adjusted such that the central axes 434 and 436 of the respective targets 420 and 424 are directed at the central portion of the substrate 416, it should be understood that in other embodiments may be intentionally aligned in other ways. For example, the sputtering sources 408 and 410 may be adjusted such that the central axes 434 and 436 are directed towards edges of the substrate 416. As will be appreciated by one skilled in the art, the optimal alignment of the sputtering sources 408 and 410 may vary depending on the particular processing being used, as well as the materials being sputtered from the targets 420 and 424.

Additionally, although the PVD tool 400 shown in FIGS. 4-6 includes a stationary substrate support 406, it should be understood that in a manufacturing environment, the substrate 416 may be in motion during the deposition process.

Furthermore, in other embodiments, the alignment devices described herein may be used is substrate processing tools configured to perform “combinatorial” processing, in which variations in the materials deposited on the substrate may be intentionally created for experimental purposes. In such an embodiment, the substrate processing tool may include an aperture positioned above the substrate to isolate particular regions of the substrate, and the alignment of the sputtering sources described herein may be in relation to the aperture, as opposed to the substrate itself.

The manufacture of semiconductor devices, thin film photovoltaic (TFPV) devices, optoelectronic devices, etc (herein collectively referred to as “device” or “devices”) entails the integration and sequencing of many unit processing steps. As an example, manufacturing typically includes a series of processing steps such as cleaning, surface preparation, deposition, patterning, etching, thermal annealing, and other related unit processing steps. The precise sequencing and integration of the unit processing steps enables the formation of functional devices meeting desired performance metrics such as efficiency, power production, and reliability.

As part of the discovery, optimization and qualification of each unit process, it is desirable to be able to i) test different materials, ii) test different processing conditions within each unit process module, iii) test different sequencing and integration of processing modules within an integrated processing tool, iv) test different sequencing of processing tools in executing different process sequence integration flows, and combinations thereof in the manufacture of devices such as integrated circuits. In particular, there is a need to be able to test i) more than one material, ii) more than one processing condition, iii) more than one sequence of processing conditions, iv) more than one process sequence integration flow, and combinations thereof, collectively known as “combinatorial process sequence integration”, on a single monolithic substrate without the need of consuming the equivalent number of monolithic substrates per material(s), processing condition(s), sequence(s) of processing conditions, sequence(s) of processes, and combinations thereof. This can greatly improve both the speed and reduce the costs associated with the discovery, implementation, optimization, and qualification of material(s), process(es), and process integration sequence(s) required for manufacturing.

Systems and methods for High Productivity Combinatorial (HPC) processing are described in U.S. Pat. No. 7,544,574 filed on Feb. 10, 2006, U.S. Pat. No. 7,824,935 filed on Jul. 2, 2008, U.S. Pat. No. 7,871,928 filed on May 4, 2009, U.S. Pat. No. 7,902,063 filed on Feb. 10, 2006, and U.S. Pat. No. 7,947,531 filed on Aug. 28, 2009, which are all herein incorporated by reference. Systems and methods for HPC processing are further described in U.S. patent application Ser. No. 11/352,077 filed on Feb. 10, 2006, claiming priority from Oct. 15, 2005, U.S. patent application Ser. No. 11/419,174 filed on May 18, 2006, claiming priority from Oct. 15, 2005, U.S. patent application Ser. No. 11/674,132 filed on Feb. 12, 2007, claiming priority from Oct. 15, 2005, and U.S. patent application Ser. No. 11/674,137 filed on Feb. 12, 2007, claiming priority from Oct. 15, 2005 which are all herein incorporated by reference.

HPC processing techniques have been successfully adapted to wet chemical processing such as etching and cleaning. HPC processing techniques have also been successfully adapted to deposition processes such as physical vapor deposition (PVD), atomic layer deposition (ALD), and chemical vapor deposition (CVD).

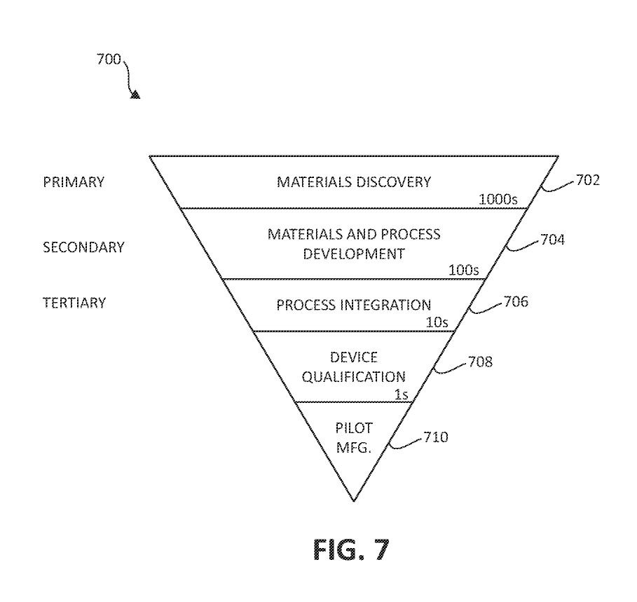

FIG. 7 illustrates a schematic diagram, 700, for implementing combinatorial processing and evaluation using primary, secondary, and tertiary screening. The schematic diagram, 700, illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages can be used to refine the success criteria and provide better screening results.

For example, thousands of materials are evaluated during a materials discovery stage, 702. Materials discovery stage, 702, is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage, 704. Evaluation of the materials is performed using metrology tools such as electronic testers and imaging tools (i.e., microscopes).

The materials and process development stage, 704, may evaluate hundreds of materials (i.e., a magnitude smaller than the primary stage) and may focus on the processes used to deposit or develop those materials. Promising materials and processes are again selected, and advanced to the tertiary screen or process integration stage, 706, where tens of materials and/or processes and combinations are evaluated. The tertiary screen or process integration stage, 706, may focus on integrating the selected processes and materials with other processes and materials.

The most promising materials and processes from the tertiary screen are advanced to device qualification, 708. In device qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes can proceed to pilot manufacturing, 710.

The schematic diagram, 700, is an example of various techniques that may be used to evaluate and select materials and processes for the development of new materials and processes. The descriptions of primary, secondary, etc. screening and the various stages, 702-710, are arbitrary and the stages may overlap, occur out of sequence, be described and be performed in many other ways.

This application benefits from High Productivity Combinatorial (HPC) techniques described in U.S. patent application Ser. No. 11/674,137 filed on Feb. 12, 2007, which is hereby incorporated for reference in its entirety. Portions of the '137 application have been reproduced below to enhance the understanding of the present invention. The embodiments described herein enable the application of combinatorial techniques to process sequence integration in order to arrive at a globally optimal sequence of manufacturing operations by considering interaction effects between the unit manufacturing operations, the process conditions used to effect such unit manufacturing operations, hardware details used during the processing, as well as materials characteristics of components utilized within the unit manufacturing operations. Rather than only considering a series of local optimums, i.e., where the best conditions and materials for each manufacturing unit operation is considered in isolation, the embodiments described below consider interactions effects introduced due to the multitude of processing operations that are performed and the order in which such multitude of processing operations are performed when fabricating a device. A global optimum sequence order is therefore derived and as part of this derivation, the unit processes, unit process parameters and materials used in the unit process operations of the optimum sequence order are also considered.

The embodiments described further analyze a portion or sub-set of the overall process sequence used to manufacture a device. Once the subset of the process sequence is identified for analysis, combinatorial process sequence integration testing is performed to optimize the materials, unit processes, hardware details, and process sequence used to build that portion of the device or structure. During the processing of some embodiments described herein, structures are formed on the processed substrate that are equivalent to the structures formed during actual production of the device. For example, such structures may include, but would not be limited to, contact layers, buffer layers, absorber layers, or any other series of layers or unit processes that create an intermediate structure found on devices. While the combinatorial processing varies certain materials, unit processes, hardware details, or process sequences, the composition or thickness of the layers or structures or the action of the unit process, such as cleaning, surface preparation, deposition, surface treatment, etc. is substantially uniform through each discrete region. Furthermore, while different materials or unit processes may be used for corresponding layers or steps in the formation of a structure in different regions of the substrate during the combinatorial processing, the application of each layer or use of a given unit process is substantially consistent or uniform throughout the different regions in which it is intentionally applied. Thus, the processing is uniform within a region (inter-region uniformity) and between regions (intra-region uniformity), as desired. It should be noted that the process can be varied between regions, for example, where a thickness of a layer is varied or a material may be varied between the regions, etc., as desired by the design of the experiment.

The result is a series of regions on the substrate that contain structures or unit process sequences that have been uniformly applied within that region and, as applicable, across different regions. This process uniformity allows comparison of the properties within and across the different regions such that the variations in test results are due to the varied parameter (e.g., materials, unit processes, unit process parameters, hardware details, or process sequences) and not the lack of process uniformity. In the embodiments described herein, the positions of the discrete regions on the substrate can be defined as needed, but are preferably systematized for ease of tooling and design of experimentation. In addition, the number, variants and location of structures within each region are designed to enable valid statistical analysis of the test results within each region and across regions to be performed.

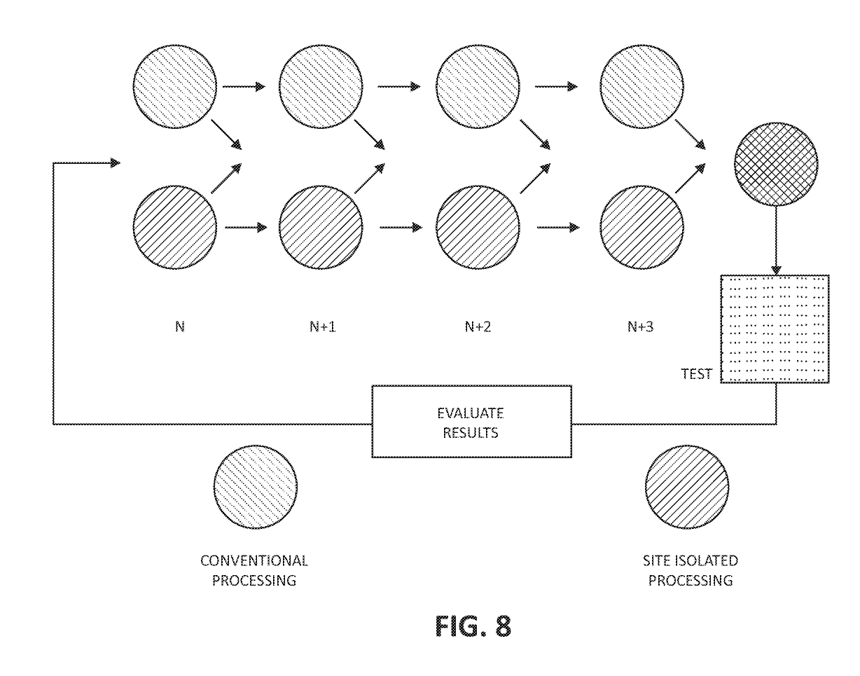

FIG. 8 is a simplified schematic diagram illustrating a general methodology for combinatorial process sequence integration that includes site isolated processing and/or conventional processing in accordance with one embodiment of the invention. In one embodiment, the substrate is initially processed using conventional process N. In one exemplary embodiment, the substrate is then processed using site isolated process N+1. During site isolated processing, an HPC module may be used, such as the HPC module described in U.S. patent application Ser. No. 11/352,077 filed on Feb. 10, 2006. The substrate can then be processed using site isolated process N+2, and thereafter processed using conventional process N+3. Testing is performed and the results are evaluated. The testing can include physical, chemical, acoustic, magnetic, electrical, optical, etc. tests. From this evaluation, a particular process from the various site isolated processes (e.g. from steps N+1 and N+2) may be selected and fixed so that additional combinatorial process sequence integration may be performed using site isolated processing for either process N or N+3. For example, a next process sequence can include processing the substrate using site isolated process N, conventional processing for processes N+1, N+2, and N+3, with testing performed thereafter.

It should be appreciated that various other combinations of conventional and combinatorial processes can be included in the processing sequence with regard to FIG. 2. That is, the combinatorial process sequence integration can be applied to any desired segments and/or portions of an overall process flow. Characterization, including physical, chemical, acoustic, magnetic, electrical, optical, etc. testing, can be performed after each process operation, and/or series of process operations within the process flow as desired. The feedback provided by the testing is used to select certain materials, processes, process conditions, and process sequences and eliminate others. Furthermore, the above flows can be applied to entire monolithic substrates, or portions of monolithic substrates such as coupons.

Under combinatorial processing operations the processing conditions at different regions can be controlled independently. Consequently, process material amounts, reactant species, processing temperatures, processing times, processing pressures, processing flow rates, processing powers, processing reagent compositions, the rates at which the reactions are quenched, deposition order of process materials, process sequence steps, hardware details, etc., can be varied from region to region on the substrate. Thus, for example, when exploring materials, a processing material delivered to a first and second region can be the same or different. If the processing material delivered to the first region is the same as the processing material delivered to the second region, this processing material can be offered to the first and second regions on the substrate at different concentrations. In addition, the material can be deposited under different processing parameters. Parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It should be appreciated that these process parameters are exemplary and not meant to be an exhaustive list as other process parameters commonly used in manufacturing may be varied.

Thus, in one embodiment, a substrate processing tool is provided. The substrate processing tool includes a plurality of sputtering sources. Each of the plurality of sputtering sources includes a target. Each target has a central axis perpendicular to a plane of the target. A device has a central axis and an indicator aligned with the central axis of the device. The indicator of the device is aligned with the central axis of the target of the sputtering source when the device is coupled to one of the plurality of sputtering sources.

In another embodiment, a method is provided. A plurality of sputtering sources positioned within a processing chamber are provided. Each of the plurality of sputtering sources includes a target. Each target has a central axis perpendicular to a plane of the target. A device is attached to a first of the plurality of sputtering sources. The device has a central axis and an indicator aligned with the central axis of the device. The indicator of the device is aligned with the central axis of the target of the first of the plurality of sputtering sources when the device is attached to the first of the plurality of sputtering sources. A direction in which the central axis of the target of the first of the plurality of sputtering sources is oriented is determined using the device. The device is attached to a second of the plurality of sputtering sources. The indicator of the device is aligned with the central axis of the target of the second of the plurality of sputtering sources when the device is attached to the second of the plurality of sputtering sources. A direction in which the central axis of the target of the second of the plurality of sputtering sources is oriented is determined using the device.

In a further embodiment, a substrate processing tool is provided. The substrate processing tool includes a housing defining a processing chamber, a substrate support coupled to the housing and configured to support a substrate within the processing chamber, a plurality of sputtering sources coupled to the housing and positioned within the processing chamber above the substrate support. Each of the plurality of sputtering sources includes a target. Each target has a central axis perpendicular to a plane of the target. A device has a central axis and an indicator aligned with the central axis of the device. The indicator of the device is aligned with the central axis of the target of the respective sputtering source when the device is coupled to one of the plurality of sputtering sources.

Although the foregoing examples have been described in some detail for purposes of clarity of understanding, the invention is not limited to the details provided. There are many alternative ways of implementing the invention. The disclosed examples are illustrative and not restrictive.

What is claimed:

1. A substrate processing tool comprising:
a plurality of sputtering sources, each of the plurality of sputtering sources comprising a target, wherein each target has a central axis perpendicular to a plane of the target; and
a device having a central axis and an indicator aligned with the central axis of the device, wherein the indicator of the device is aligned with the central axis of the target of the sputtering source when the device is coupled to one of the plurality of sputtering sources.

2. The substrate processing tool of claim 1, wherein the device comprises an electromagnetic radiation source configured to emit electromagnetic radiation along the central axis of the device.

3. The substrate processing tool of claim 2, wherein the electromagnetic radiation source is a laser.

4. The substrate processing tool of claim 1, further comprising:
a housing defining a processing chamber, wherein the plurality of sputtering sources are coupled to the housing and positioned within the processing chamber; and
a substrate support coupled to the housing and configured to support a substrate within the processing chamber.

5. The substrate processing tool of claim 4, wherein the plurality of sputtering sources are coupled to the housing such that the respective directions in which the central axis of each of the targets are adjustable.

6. The substrate processing tool of claim 5, wherein the plurality of sputtering sources are coupled to the housing such that respective distances between each of the plurality of sputtering sources and the substrate support are adjustable.

7. A method comprising:
providing a plurality of sputtering sources positioned within a processing chamber, each of the plurality of sputtering sources comprising a target, wherein each target has a central axis perpendicular to a plane of the target;
attaching a device to a first of the plurality of sputtering sources, the device having a central axis and an indicator aligned with the central axis of the device, wherein the indicator of the device is aligned with the central axis of the target of the first of the plurality of sputtering sources when the device is attached to the first of the plurality of sputtering sources;
determining a direction in which the central axis of the target of the first of the plurality of sputtering sources is oriented using the device;
attaching the device to a second of the plurality of sputtering sources, wherein the indicator of the device is aligned with the central axis of the target of the second of the plurality of sputtering sources when the device is attached to the second of the plurality of sputtering sources; and
determining a direction in which the central axis of the target of the second of the plurality of sputtering sources is oriented using the device.

8. The method of claim 7, wherein the device comprises an electromagnetic radiation source configured to emit electromagnetic radiation along the central axis of the device.

9. The method of claim 8, wherein the electromagnetic radiation source is a laser.

10. The method of claim 7, wherein the substrate processing tool further comprises:
a housing defining the processing chamber, wherein the plurality of sputtering sources are coupled to the housing; and
a substrate support coupled to the housing and configured to support a substrate within the processing chamber.

11. The method of claim 10, wherein the plurality of sputtering sources are coupled to the housing such that the respective directions in which the central axis of each of the targets are adjustable and respective distances between each of the first sputtering sources and the substrate support are adjustable.

12. The method of claim 10, further comprising:
moving the first of the plurality of sputtering sources relative to the housing to adjust the direction in which the central axis of the target of the first of the plurality of sputtering sources is oriented; and
detaching the device from the first of the plurality of sputtering sources.

13. The method of claim 12, further comprising:
attaching the device to a second of the plurality of sputtering sources
moving the second of the plurality of sputtering sources relative to the housing to adjust the direction in which the central axis of the target of the second of the plurality of sputtering sources is oriented; and
detaching the device from the second of the plurality of sputtering sources.

14. The method of claim 12, further comprising sputtering particles from the target of the first of the plurality of sputtering sources such that the particles are deposited on the substrate.

15. A substrate processing tool comprising:
a housing defining a processing chamber;
a substrate support coupled to the housing and configured to support a substrate within the processing chamber;
a plurality of sputtering sources coupled to the housing and positioned within the processing chamber above the substrate support, each of the plurality of sputtering sources comprising a target, wherein each target has a central axis perpendicular to a plane of the target; and
a device having a central axis and an indicator aligned with the central axis of the device, wherein the indicator of the device is aligned with the central axis of the target of the respective sputtering source when the device is coupled to one of the plurality of sputtering sources.

16. The substrate processing tool of claim 15, wherein the device comprises an electromagnetic radiation source configured to emit electromagnetic radiation along the central axis of the device.

17. The substrate processing tool of claim 16, wherein the electromagnetic radiation source is a laser.

18. The substrate processing tool of claim 17, wherein the plurality of sputtering sources are coupled to the housing such that the respective directions in which the central axis of each of the targets are adjustable.

19. The substrate processing tool of claim 18, wherein the plurality of sputtering sources are coupled to the housing such that respective distances between each of the plurality of sputtering sources and the substrate support are adjustable.

20. The substrate processing tool of claim 15, wherein the device is configured to be detachably coupled to each of the plurality of sputtering sources.
